(19) United States
(12) Patent Application Publication
(10) Pub. No.: US 2025/0385159 A1
(43) Pub. Date: Dec. 18, 2025

(54) Semiconductor Cooling Device, Power Conversion Device, and Method for Manufacturing Semiconductor Cooling Device

(71) Applicant: Hitachi Astemo, Ltd., Hitachinaka-shi, Ibaraki (JP)

(72) Inventors: Ti CHEN, Tokyo (JP); Takeshi TOKUYAMA, Tokyo (JP); Shigehisa AOYAGI, Hitachinaka-shi, Ibaraki (JP); Hideki MIYAZAKI, Hitachinaka-shi, Ibaraki (JP); Akihiro NAMBA, Tokyo (JP); Takahiro ARAKI, Tokyo (JP)

(21) Appl. No.: 18/878,800

(22) PCT Filed: Apr. 14, 2023
(86) PCT No.: PCT/JP2023/015220

§ 371 Date: Dec. 24, 2024

(30) Foreign Application Priority Data
Jul. 7, 2022 (JP) 2022-109942

(51) Int. Cl. H01L 23/473

(52) U.S. Cl. CPC H01L 23/473

(57) ABSTRACT

A semiconductor cooling device includes a plurality of semiconductor modules, a plurality of first refrigerant flow paths provided corresponding to the semiconductor modules, and a pair of flow path pipes connected to the plurality of first refrigerant flow paths. The plurality of semiconductor modules are arranged on a substrate side by side in a first direction so as to face the plurality of first refrigerant flow paths, respectively. Each of the pair of flow path pipes extends along the first direction. In each of the plurality of semiconductor modules, a heat dissipation surface in contact with each of the plurality of first refrigerant flow paths is disposed in an intersecting direction with respect to an extending direction of the first refrigerant flow paths and an arrangement direction of the plurality of semiconductor modules. The first refrigerant flow path includes a deformable portion that is deformable in the intersecting direction.

### TECHNICAL FIELD

The present invention relates to a semiconductor cooling device, a power conversion device, and a method for manufacturing a semiconductor cooling device.

### BACKGROUND ART

The inverter can realize high output and low cost by utilizing a semiconductor module that can be mass-produced and integrating main circuit wiring using a printed circuit board. However, in the case of cooling both surfaces of a plurality of semiconductor modules, in order to reduce the thermal resistance, high dimensional accuracy is required for the semiconductor modules and the cooling water channel, and the cost becomes high. However, among these, miniaturization and height reduction are strictly required.

PTL 1 below discloses a configuration of a cooler capable of sufficiently securing a contact area between an electronic component and a tube without increasing the number of components.

### CITATION LIST

### Patent Literature

PTL 1: JP 2005-228877 A

### SUMMARY OF INVENTION

### Technical Problem

In a conventional structure, when a semiconductor module is mounted on a substrate, each module has a certain level difference, and each semiconductor module may not have followability with respect to a water path in contact with the semiconductor module. Therefore, even if the cost reduction can be realized, there is a problem that the reliability as the cooling device is lowered due to the variation in the heat dissipation surface caused by such a height difference. In view of this, an object of the present invention is to provide a semiconductor cooling device and a method for manufacturing the semiconductor cooling device that achieve miniaturization, cost reduction, and high heat dissipation.

### Solution to Problem

A semiconductor cooling device includes a plurality of semiconductor modules each having a semiconductor element built therein, a plurality of first refrigerant flow paths respectively provided corresponding to the plurality of semiconductor modules, and a pair of flow path pipes respectively connected to inlets and outlets of the plurality of first refrigerant flow paths. The plurality of semiconductor modules are arranged on a substrate side by side in a first direction so as to face the plurality of first refrigerant flow paths, respectively. Each of the pair of flow path pipes extends along the first direction. In each of the plurality of semiconductor modules, a heat dissipation surface in contact with each of the plurality of first refrigerant flow paths is disposed in an intersecting direction with respect to an extending direction of the first refrigerant flow paths and an arrangement direction of the plurality of semiconductor modules. The first refrigerant flow path includes a deformable portion that is deformable in the intersecting direction at a portion connected to the flow path pipe.

In addition, as a method for manufacturing a semiconductor cooling device, there is adopted a method including joining a plurality of first refrigerant flow paths respectively provided corresponding to a plurality of semiconductor modules each having a semiconductor element built therein and arranged side by side on a substrate, and a pair of flow path pipes connected to the plurality of first refrigerant flow paths and extending along an arrangement direction of the plurality of semiconductor modules, and mounting the plurality of joined first refrigerant flow paths and the pair of flow path pipes on the semiconductor module.

As another method for manufacturing a semiconductor cooling device, there is adopted a method including joining a plurality of first refrigerant flow paths respectively provided corresponding to a plurality of semiconductor modules each having a semiconductor element built therein and arranged side by side on a substrate, and joining a pair of flow path pipes extending along an arrangement direction of the plurality of semiconductor modules to the plurality of first refrigerant flow paths.

### Advantageous Effects of Invention

It is possible to provide a semiconductor cooling device and a method for manufacturing the semiconductor cooling device that achieve miniaturization, cost reduction, and high heat dissipation.

### BRIEF DESCRIPTION OF DRAWINGS

FIG. 1 is an overall perspective view of a semiconductor cooling device according to an embodiment of the present invention.

FIG. 2 is a cross-sectional view taken along line Y-Y of FIG. 1.

FIG. 3 is a cross-sectional view taken along line X-X of FIG. 1.

FIG. 4 is a first modification of FIG. 3.

FIG. 5 is a second modification of FIG. 3.

FIG. 6 is a modification (third modification) of FIG. 2.

FIG. 7 illustrates an example of a method for manufacturing a semiconductor cooling device.

Hereinafter, embodiments of the present invention will be described with reference to the drawings. The following description and drawings are exemplifications for describing the present invention, and are omitted and simplified as appropriate for clarification of the description. The present invention can be implemented in other various forms. Unless otherwise limited, each component may be singular or plural.

The position, size, shape, range, and the like of each component illustrated in the drawings may not necessarily represent the actual position, size, shape, range, and the like, in order to facilitate understanding of the invention. For this reason, the present invention is not necessarily limited to the position, size, shape, range, and the like disclosed in the drawings.

### Overall Configuration of Embodiment and Device of Present Invention

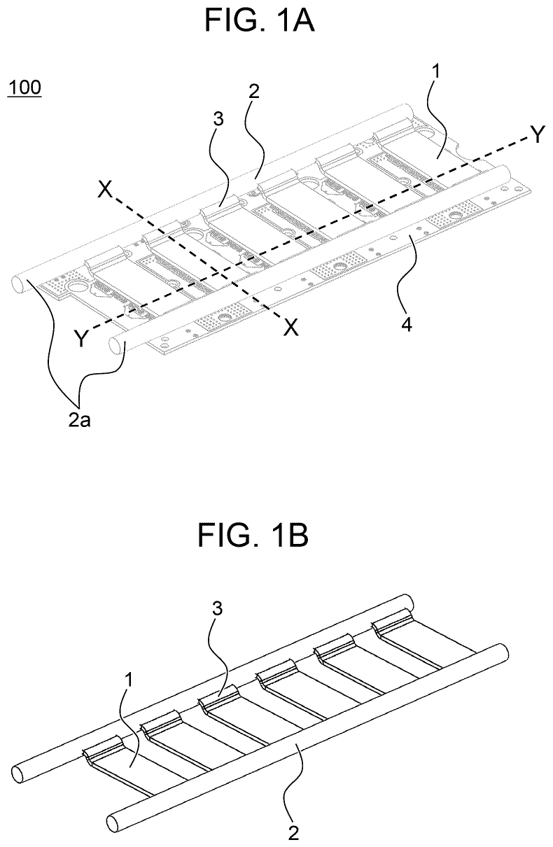

### FIG. 1

FIG. 1 (a) is an overall perspective view illustrating a semiconductor cooling device mounted on a plurality of semiconductor modules included in a substrate, and FIG. 1 (b) is a perspective view of the semiconductor cooling device. A semiconductor cooling device 100 (hereinafter, referred to as a cooling device 100) includes a printed circuit board 4 (hereinafter, referred to as a substrate 4) that commonly fixes a plurality of semiconductor modules each of which serves as a power converter of the power conversion device, a plurality of small piece cooling flow paths 1 (hereinafter, referred to as a first refrigerant flow path 1), and a pair of cooling flow path pipes 2 (hereinafter, referred to as a flow path pipe 2).

Each of the plurality of first refrigerant flow paths 1 is connected to the pair of flow path pipes 2 at both ends. A deformable portion 3 (details will be described later) is provided at a connection portion between the plurality of first refrigerant flow paths 1 and the pair of flow path pipes 2. The pair of flow path pipes 2 takes in the refrigerant from the outside through a flow path inlet/outlet 2a, and causes the refrigerant to flow through each of the plurality of first refrigerant flow paths 1. Since the first refrigerant flow path 1 is joined to the flow path pipes 2 in parallel, the refrigerant having the equal flow rate and the same temperature flows through the flow path at the contact portion with each phase of the semiconductor module 10, and the temperature difference between the phases of the semiconductor module 10 can be reduced.

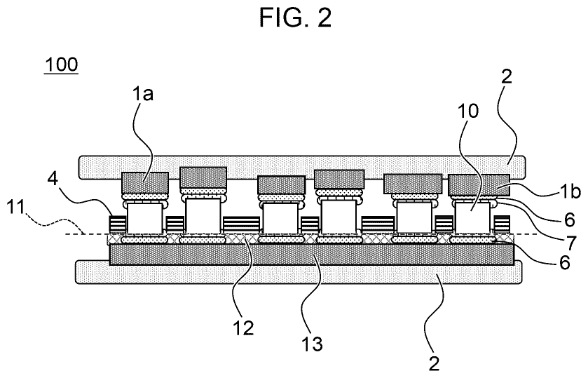

### FIG. 2

The cooling includes a plurality of device 100 semiconductor modules 10 each having a semiconductor element built therein, a plurality of first refrigerant flow paths 1 respectively provided corresponding to a plurality of semiconductor modules 10, and a pair of flow path pipes 2 respectively connected to inlets and outlets of the plurality of first refrigerant flow paths 1.

In the first refrigerant flow path 1, in a case where the inlet side of the refrigerant flowing from the flow path pipe 2 is defined as the front side and the outlet side of the refrigerant is defined as the rear side, a first refrigerant flow path 1b on the rear side connected to the flow path pipe 2 at a position close to the outlet side of the flow path pipe 2 may be formed to be wider than a first refrigerant flow path 1a on the front side connected to the flow path pipe 2 at a position close to the inlet side of the flow path pipe 2. As a result, in the first refrigerant flow path 1, the pressure loss in the first refrigerant flow path 1b on the rear side does not increase due to the refrigerant flowing inside, so that the pressure can be reduced as a whole.

In the cooling device 100, a sheet-like insulating member 6 and a heat dissipation member 7 are bonded to a surface facing the semiconductor module 10 in the first refrigerant flow path 1. This eliminates the need for a fixing member for fixing the insulating member 6. The insulating member 6 is a material having insulating properties and adhesion, such as a silicone resin sheet. The heat dissipation member 7 is, for example, a thermal interface material (TIM).

In the plurality of semiconductor modules 10 included in the substrate 4, the first refrigerant flow path 1 is disposed on one surface, and a second refrigerant flow path 13 is disposed on the other surface. By disposing the refrigerant flow paths on both surfaces of the semiconductor module 10 in this manner, cooling performance of the semiconductor module 10 is improved. In the second refrigerant flow path 13, the sheet-like insulating member 6 is bonded on a surface facing the semiconductor module 10.

The second refrigerant flow path 13 is disposed to face the first refrigerant flow path 1 via the semiconductor module 10, and is formed to be wider than the first refrigerant flow path 1. Thus, the substrate 4 can be cooled. Similarly to the first refrigerant flow path 1, the second refrigerant flow path 13 is connected to the pair of flow path pipes 2. A second heat dissipation member 12 is disposed between the second refrigerant flow path 13 and the substrate 4. As a result, the second refrigerant flow path 13 and the substrate 4 are brought into close contact with each other via the second heat dissipation member 12, so that cooling performance is improved. The second heat dissipation member 12 is, for example, a gap filler or a heat dissipation sheet.

The second refrigerant flow path 13 cools the plurality of semiconductor modules 10 on one surface, and has higher rigidity than the first refrigerant flow path 1. This improves followability of the first refrigerant flow path 1 to the semiconductor module 10 when the first refrigerant flow path 1 is screwed.

The substrate 4 is a printed circuit board, and is formed of an electrically conductive member such as a copper bus bar. That is, the substrate 4 has both a function of fixing the semiconductor module 10 and a function of electrical conduction. The substrate 4 has a plurality of wiring layers respectively connected to the plurality of semiconductor modules 10 and including a DC wiring through which a direct current flows and an AC wiring through which an alternating current flows. As a result, it is possible to realize a power conversion device including the cooling device 100 that realizes miniaturization, cost reduction, and high heat dissipation.

In addition, the member mounted on each of the plurality of semiconductor modules 10 is the substrate 4, and the semiconductor modules are mounted in common, so that, for example, a reference surface 11 in a case where the semiconductor modules 10 are installed in the second refrigerant flow path 13 is easily taken in a process, and productivity and mountability are improved.

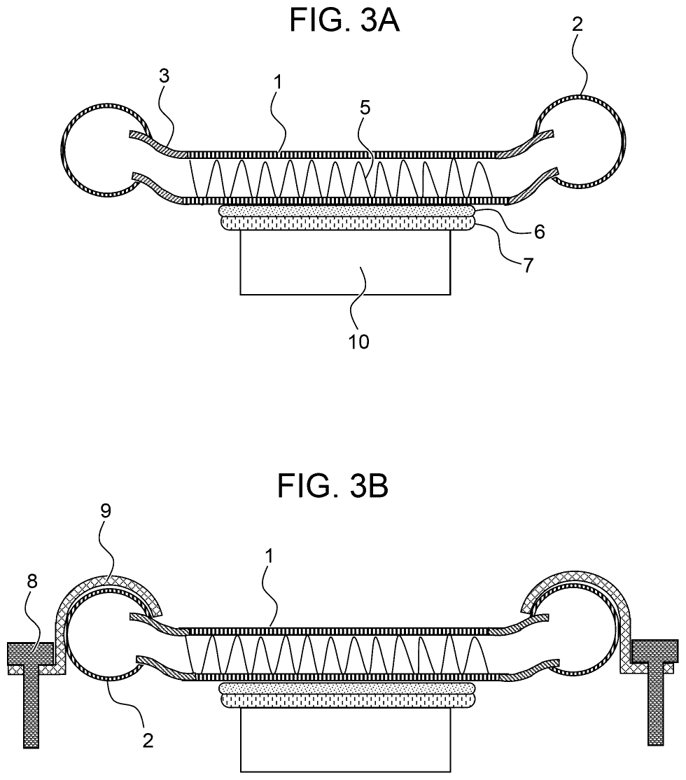

### FIG. 3

FIG. 3 (a) is a cross-sectional view taken along line X-X of FIG. 1, and FIG. 3 (b) is a view for explaining a member for fixing the configuration of FIG. 3 (a). The first refrigerant flow path 1 includes a deformable portion 3 which is deformable in the intersecting direction at a connection portion with the pair of flow path pipes 2. The deformable portion 3 is, for example, an elastic material such as aluminum or a spring. The first refrigerant flow path 1 includes a heat dissipation fin 5 therein. The heat dissipation fin 5 is a high thermal conductive member such as aluminum or copper.

The pair of flow path pipes 2 connected to the first refrigerant flow path 1 is covered with a water path fixing member 9 such as a leaf spring, and the first refrigerant flow path 1 is pressed against and fixed to the plurality of semiconductor modules 10 mounted on the substrate 4 by fastening and fixing the water path fixing member 9 to a housing or the like (not illustrated) of the power conversion device by a screw 8. This improves adhesion between the first refrigerant flow path 1 and the semiconductor module 10.

The deformable portion 3 has a shape that is easily deformed, such as a wavy shape or a thin shape. The rigidity of the deformable portion 3 is lower than the rigidity of the first refrigerant flow path 1. When the first refrigerant flow paths 1 are pressed against the plurality of semiconductor modules 10, the deformable portion 3 is deformed by the fastening force. This improves adhesion between the first refrigerant flow path 1 and the semiconductor module 10.

Here, it can be seen from FIGS. 1 to 3 that the plurality of semiconductor modules 10 face the plurality of first refrigerant flow paths 1, and are arranged side by side in the first direction on the substrate 4, and the pair of flow path pipes 2 extend along the first direction. In the plurality of semiconductor modules 10, it can be seen that the respective heat dissipation surfaces in contact with the plurality of first refrigerant flow paths 1 are disposed in the intersecting direction (the vertical direction side in FIG. 3) with respect to the extending direction of the first refrigerant flow paths 1 (the left-right direction in FIG. 3) and the arrangement direction of the plurality of semiconductor modules 10 (the near-depth direction in FIG. 3). The intersecting direction here refers to a wide range on the side perpendicular to the extending direction of the first refrigerant flow path 1 and the arrangement direction of the semiconductor modules 10 described above.

With such a configuration, the adhesion between the heat dissipation fin 5 and the semiconductor module 10 via the flow path wall of the first refrigerant flow path 1 is improved while improving the reliability of the cooling device 100. In addition, since the deformable portion 3 deforms not in the arrangement direction of the semiconductor modules 10 but on a side in the intersecting direction, the configuration of the first refrigerant flow paths 1 is arranged in parallel on the same plane along the substrate 4 while absorbing the thickness tolerance of each of the semiconductor modules 10 with respect to the first refrigerant flow paths 1, so that the first refrigerant flow paths 1 themselves can be thinned. Therefore, the height of the entire cooling device 100 can be reduced.

### First Modification

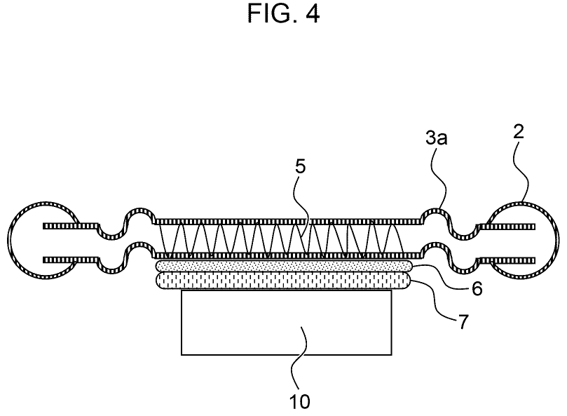

### FIG. 4

The deformable portion 3 may be, for example, an S-shaped deformable portion 3a formed in an S-shape. As a result, since the first refrigerant flow path 1 is provided on the same plane as the pair of flow path pipes 2, the height of the cooling device 100 can be reduced.

### Second Modification

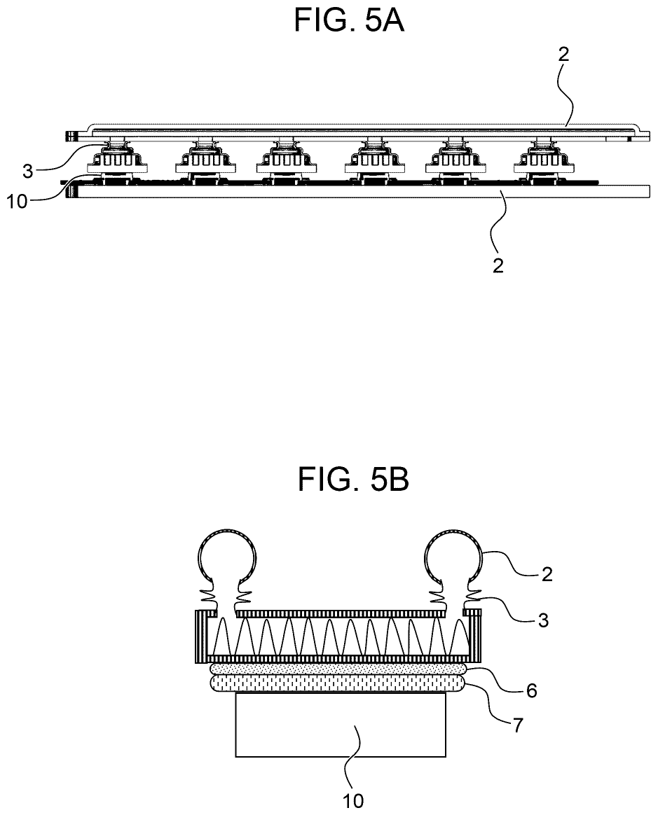

### FIG. 5

FIG. 5 (a) is a cross-sectional view of a part of the configuration of the second modification of FIG. 3, and FIG. 5 (b) is a cross-sectional view of a part of the configuration of the modification illustrated in FIG. 5 (a). The pair of flow path pipes 2 is provided in the above-described intersecting direction with respect to the first refrigerant flow path 1, and accordingly, the deformable portion 3 is also provided in the above-described intersecting direction with respect to the first refrigerant flow path 1. The deformable portion 3 is formed of, for example, a bellows. As a result, the floor area of the first refrigerant flow path 1 is reduced. In addition, since the deformable portion 3 is deformed by being compressed in the vertical direction (intersecting direction), the followability to the semiconductor module 10 in the intersecting direction is improved, and the reliability as the cooling device 100 is improved. The deformable portion 3 is formed of a low-cost component such as a press, thereby reducing the cost of the entire first refrigerant flow path 1. The pair of flow path pipes 2 is formed of a cylindrical shape, a low-cost press plate, or the like.

### Third Modification

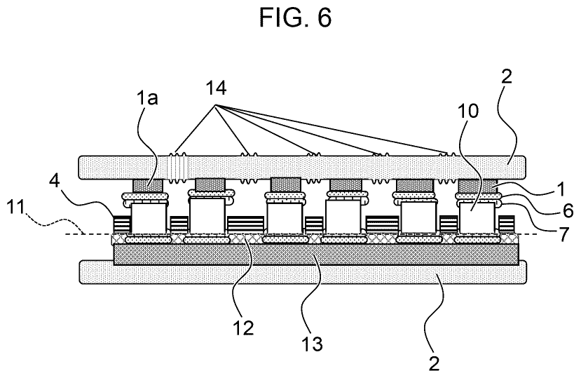

### FIG. 6

Each of the flow path pipes 2 has a bellows 14 between positions connected to the plurality of first refrigerant flow paths 1. With such a structure, the first refrigerant flow path 1 improves the followability for each arm of the semiconductor modules 10, and more easily absorbs the tolerance of each of the semiconductor modules 10 in the intersecting direction.

### Method for Manufacturing Semiconductor Cooling Device

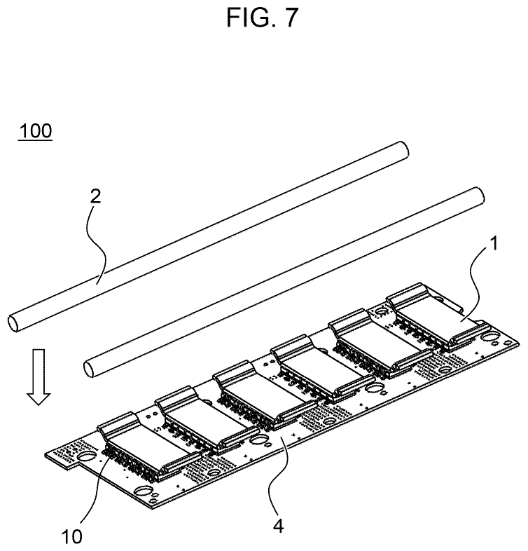

### FIG. 7

A method for manufacturing the cooling device 100 is, for example, as follows. First, the plurality of first refrigerant flow paths 1 respectively provided corresponding to the plurality of semiconductor modules 10 each having a semiconductor element built therein and arranged side by side on the substrate 4 and the pair of flow path pipes 2 connected to the plurality of first refrigerant flow paths 1 and extending along the arrangement direction of the plurality of semiconductor modules 10 are joined. Subsequently, the plurality of joined first refrigerant flow paths 1 and flow path pipes 2 are mounted on the semiconductor module 10. Since such a manufacturing method is adopted, in the step of mounting the first refrigerant flow path 1 on the semiconductor module 10 in a bonded state, inspection can be performed with the first refrigerant flow path alone, the number of steps can be reduced, and the yield can be improved.

As another method for manufacturing the cooling device 100, there is the following method illustrated in FIG. 7. First, the plurality of first refrigerant flow paths 1 respectively provided correspondingly are joined to the plurality of semiconductor modules 10 each having a semiconductor element built therein and arranged side by side on the substrate 4. Next, as illustrated in FIG. 7, the pair of flow path pipes 2 extending along the arrangement direction of the plurality of semiconductor modules 10 is joined to the plurality of first refrigerant flow paths 1. By adopting such a manufacturing method, stress at a joint portion between the first refrigerant flow path 1 and the flow path pipe 2 can be reduced.

Although the semiconductor cooling device 100 according to the present invention has been described above, for example, the first refrigerant flow path 1 may have a three-division configuration in which the semiconductor modules 10 are pressed by two rows of the first refrigerant flow path 1 instead of the above-described configuration in which the first refrigerant flow path 1 is divided into six corresponding to each phase of the semiconductor modules 10 to absorb tolerance. Although the configuration in which one second refrigerant flow path 13 is provided has been described above, one first refrigerant flow path 1 may be provided, and the second refrigerant flow path 13 may be divided so as to correspond to each phase of the semiconductor module 10.

According to the embodiment of the present invention described above, the following operational advantages are achieved.
(1) A plurality of semiconductor modules 10 each having a semiconductor element built therein, a plurality of first refrigerant flow paths 1 respectively provided corresponding to a plurality of semiconductor modules 10, and a pair of flow path pipes 2 respectively connected to inlets and outlets of the plurality of first refrigerant flow paths 1 are provided. The plurality of semiconductor modules 10 are arranged on the substrate 4 side by side in the first direction so as to face the plurality of first refrigerant flow paths 1, respectively. The pair of flow path pipes 2 extend along the first direction, and in the plurality of semiconductor modules 10, the respective heat dissipation surfaces in contact with the plurality of first refrigerant flow paths 1 are disposed in the direction intersecting the extending direction of the first refrigerant flow paths 1 and the arrangement direction of the plurality of semiconductor modules 10. The first refrigerant flow path 1 includes a deformable portion 3 that is deformable in the intersecting direction at a portion connected to the flow path pipe 2. With this configuration, it is possible to provide a semiconductor cooling device that achieves miniaturization, cost reduction, and high heat dissipation.
(2) The deformable portion 3 is provided in an intersecting direction with respect to the first refrigerant flow path 1. With such a configuration, since the deformable portion 3 is deformed in the vertical compression direction, the followability to the semiconductor module 10 in the intersecting direction is improved, so that the reliability is improved.
(3) The deformable portion 3 is formed in an S shape. With such a configuration, since the first refrigerant flow path 1 is provided on the same plane as the flow path pipe 2, the height can be reduced.
(4) In the semiconductor module 10, the first refrigerant flow path 1 is disposed on one surface, and a second refrigerant flow path 2 is disposed on the other surface. Thus, both surfaces of the semiconductor module 10 can be cooled.
(5) The second refrigerant flow path 2 is disposed to face the first refrigerant flow path 1 via the semiconductor module 10, and is formed to be wider than the first refrigerant flow path 1. The heat dissipation member 12 is disposed between the second refrigerant flow path 2 and the substrate 4. With such a configuration, since the semiconductor module 10 and the substrate 4 are in close contact with each other, cooling performance is improved.
(6) The second refrigerant flow path 2 cools the plurality of semiconductor modules 10 on one surface, and has higher rigidity than the first refrigerant flow path 1. With such a configuration, followability of the first refrigerant flow path 1 to the semiconductor module 10 at the time of screw fastening is improved.
(7) In the plurality of first refrigerant flow paths 1, the first refrigerant flow path 1b connected to the flow path pipe 2 at a position close to the outlet side of the flow path pipe 2 is wider than the first refrigerant flow path la connected to the flow path pipe 2 at a position close to the inlet side of the flow path pipe 2. With such a configuration, the substrate 4 can be cooled.
(8) The insulating member 6 is bonded to a surface of each of the first refrigerant flow path 1 and the second refrigerant flow path, the surface facing the semiconductor module 10. With such a configuration, it is not necessary for a fixing member to fix the insulating member 6.
(9) The power conversion device includes the semiconductor cooling device 100, and the substrate 4 includes a plurality of wiring layers respectively connected to the plurality of semiconductor modules 10 and including a DC wiring through which a direct current flows and an AC wiring through which an alternating current flows. With this configuration, it is possible to provide a power conversion device that achieves miniaturization, cost reduction, and high heat dissipation.
(10) As a method for manufacturing the semiconductor cooling device 100, first, the plurality of first refrigerant flow paths 1 respectively provided corresponding to the plurality of semiconductor modules 10 each having a semiconductor element built therein and arranged side by side on the substrate 4 and the pair of flow path pipes 2 connected to the plurality of first refrigerant flow paths 1 and extending along the arrangement of direction the plurality of semiconductor modules 10 are joined. Then, a method for mounting the plurality of joined first refrigerant flow paths 1 and flow path pipes 2 on the semiconductor module 10 is adopted. With such a configuration, the number of steps can be reduced, and the yield can be improved.
(11) As a method for manufacturing the semiconductor cooling device 100, first, the plurality of first refrigerant flow paths 1 respectively provided correspondingly are joined to the plurality of semiconductor modules 10 each having a semiconductor element built therein and arranged side by side on the substrate 4. Then, a method for joining a pair of flow path pipes 2 extending along the arrangement direction of the plurality of semiconductor modules 10 to the plurality of first refrigerant flow paths 1 is adopted. With such a configuration, stress at the joint portion between the first refrigerant flow path 1 and the flow path pipe 2 can be reduced.

Note that the present invention is not limited to the above embodiments, and various modifications and other configurations can be combined without departing from the gist of the present invention. Further, the invention is not limited to the one having all the configurations described in the above-described embodiments, and includes ones in which a part of the configuration is deleted.

### REFERENCE SIGNS LIST

1 small piece cooling water passage (first refrigerant flow path)
1a first refrigerant flow path on front side
1b first refrigerant flow path on rear side
2 refrigerant flow path pipe
2a flow path inlet/outlet
3 deformable portion
3a S-shaped deformable portion
4 printed circuit board
5 heat dissipation fin
6 insulating member
7 heat dissipation member
8 screw
9 water path fixing member
10 semiconductor module
11 reference surface
12 second heat dissipation member
13 second refrigerant flow path
14 bellows
100 semiconductor cooling device (cooling device)

1. A semiconductor cooling device comprising:
a plurality of semiconductor modules each having a semiconductor element built therein;
a plurality of first refrigerant flow paths respectively provided corresponding to the plurality of semiconductor modules; and
a pair of flow path pipes respectively connected to inlets and outlets of the plurality of first refrigerant flow paths, wherein
the plurality of semiconductor modules are arranged on a substrate side by side in a first direction so as to face the plurality of first refrigerant flow paths, respectively,
each of the pair of flow path pipes extends along the first direction,
in each of the plurality of semiconductor modules, a heat dissipation surface in contact with each of the plurality of first refrigerant flow paths is disposed in an intersecting direction with respect to an extending direction of the first refrigerant flow paths and an arrangement direction of the plurality of semiconductor modules, and
the first refrigerant flow path includes a deformable portion that is deformable in the intersecting direction at a portion connected to the flow path pipe.

2. The semiconductor cooling device according to claim 1, wherein the deformable portion is provided in the intersecting direction with respect to the first refrigerant flow path.

3. The semiconductor cooling device according to claim 1, wherein the deformable portion is formed in an S shape.

4. The semiconductor cooling device according to claim 1, wherein in the semiconductor module, the first refrigerant flow path is disposed on one surface, and the second refrigerant flow path is disposed on an other surface.

5. The semiconductor cooling device according to claim 4, wherein
the second refrigerant flow path is disposed to face the first refrigerant flow path via the semiconductor module, and is formed to be wider than the first refrigerant flow path, and
a heat dissipation member is disposed between the second refrigerant flow path and the substrate.

6. The semiconductor cooling device according to claim 4, wherein the second refrigerant flow path cools the plurality of semiconductor modules on one surface and has higher rigidity than that of the first refrigerant flow path.

7. The semiconductor cooling device according to claim 1, wherein in the plurality of first refrigerant flow paths, the first refrigerant flow path connected to the flow path pipe at a position close to an outlet side of the flow path pipe is wider than the first refrigerant flow path connected to the flow path pipe at a position close to an inlet side of the flow path pipe.

8. The semiconductor cooling device according to claim 4, wherein an insulating member is bonded to a surface of each of the first refrigerant flow path and the second refrigerant flow path, the surface facing the semiconductor module.

9. A power conversion device comprising
the semiconductor cooling device according to claim 1, wherein
the substrate includes a plurality of wiring layers respectively connected to the plurality of semiconductor modules and including a DC wiring through which a direct current flows and an AC wiring through which an alternating current flows.

10. A method for manufacturing a semiconductor cooling device, the method comprising:
joining a plurality of first refrigerant flow paths respectively provided corresponding to a plurality of semiconductor modules each having a semiconductor element built therein and arranged side by side on a substrate, and a pair of flow path pipes connected to the plurality of first refrigerant flow paths and extending along an arrangement direction of the plurality of semiconductor modules; and
mounting the plurality of joined first refrigerant flow paths and the pair of flow path pipes on the semiconductor module.

11. A method for manufacturing a semiconductor cooling device, the method comprising:
joining a plurality of first refrigerant flow paths respectively provided corresponding to a plurality of semiconductor modules each having a semiconductor element built therein and arranged side by side on a substrate; and
joining a pair of flow path pipes extending along an arrangement direction of the plurality of semiconductor modules to the plurality of first refrigerant flow paths.
